(19) United States
(12) Patent Application Publication
(10) Pub. No.: US 2025/0051954 A1
(43) Pub. Date: Feb. 13, 2025

(54) ELECTROPLATING DEVICE

(71) Applicant: ACM RESEARCH (SHANGHAI), INC., Shanghai (CN)

(72) Inventors: Hui Wang, Shanghai (CN); Jian Wang, Shanghai (CN); Ruofei Wang, Shanghai (CN); Zhaowei Jia, Shanghai (CN); Hongchao Yang, Shanghai (CN)

(73) Assignee: ACM RESEARCH (SHANGHAI), INC., Shanghai (CN)

(21) Appl. No.: 18/720,419

(22) PCT Filed: Nov. 24, 2022
(86) PCT No.: PCT/CN2022/134032

§ 371 Date: Jun. 14, 2024

(30) Foreign Application Priority Data
Dec. 14, 2021 (CN) 202111529125.X

(51) Int. Cl. C25D 17/02; C25D 17/00; C25D 21/04

(52) U.S. Cl. CPC C25D 17/02; C25D 21/04; C25D 17/004

(57) ABSTRACT

An electroplating device includes a process chamber, a substrate holding device, a first cover body, a second cover body, a gas supply part and an exhaust part. The electroplating solution is contained in the inner chamber of the process chamber and the inner chamber has an opening. The substrate holding device is used for holding a substrate, and the substrate holding device is moved into or out of the inner chamber through the opening. The first cover body is connected to the substrate holding device to close the opening after the substrate holding device is moved into the inner chamber, so that the inner chamber is in a closed state. The second cover body is used for closing the opening after the substrate holding device is moved out of the inner chamber, so that the inner chamber is in the closed state again.

### BACKGROUND OF THE INVENTION

### Field of the Invention

The present invention relates to the technical field of semiconductor manufacturing, in particular to an electroplating device.

### The Related Art

In the electroplating process, the stability of electroplating solution composition is particularly important for the reliability of electroplated products.

During the electroplating process, the lifting driving device in the electroplating device drives the substrate to descend and immerse in the electroplating solution in the process chamber through the substrate holding device, so as to electroplate the substrate. After electroplating process, the lifting driving device drives the substrate to rise and move out of the process chamber through the substrate holding device.

However, the electroplating solution in the process chamber may have stability problems when electroplating is not performed or electroplating is performed. For example, the sulfite ions in the gold-plating solution are easily oxidized by oxygen in the air, resulting in unstable technological parameters of the gold plating and shorter service life, which brings inconvenience to production and management.

### SUMMARY

The present invention aims to solve the problem of stability of the electroplating solution in the process chamber in the prior art. Accordingly, the present invention provides an electroplating device, which has the advantages of preventing the electroplating solution from being oxidized and maintaining the stability of the electroplating solution.

To achieve the above objective, the present invention proposes an electroplating device, comprising:
a process chamber, having an inner chamber for holding the electroplating solution, the inner chamber having an opening;
a substrate holding device for holding a substrate, the substrate holding device moving into or out of the inner chamber through the opening;
a first cover body, connected to the substrate holding device to close the opening after the substrate holding device is moved into the inner chamber so that the inner chamber is in a closed state;
a second cover body, closing the opening after the substrate holding device is moved out of the inner chamber so that the inner chamber is in a closed state;
a gas supply part, introducing an inert gas into the inner chamber; and
an exhaust part, discharging air from the inner chamber.

In one embodiment of the present invention, the first cover body is a rotary driving device, and the rotary driving device drives the substrate holding device to rotate in the inner chamber around the axis of said rotary driving device. When the substrate holding device is moved into the inner chamber, the rotary driving device covers the opening so as to close it.

In one embodiment of the present invention, an enclosure is provided along the circumferential direction of the lower surface of the first cover body towards the opening. When the first cover body covers the opening, the enclosure is in contact with an edge of the opening.

In one embodiment of the present invention, a sealing ring is provided at a position where the opening is combined with the first cover body or the second cover body.

In one embodiment of the present invention, the second cover body comprises two cover bodies that cooperate with each other, and both cover bodies are at the same plane. After the substrate holding device is moved out of the inner chamber, the two cover bodies are moved towards the center of the opening to close the opening.

In one embodiment of the present invention, the exhaust part comprises a first exhaust part and a second exhaust part, the first exhaust part is provided in the first cover body and the second exhaust part is provided in the second cover body.

In one embodiment of the present invention, the process chamber comprises a shield, the gas supply part is arranged on the shield, and the gas supply part comprises a plurality of gas inlet channels, which are arranged at intervals along the circumferential direction of the shield and pass through the side wall of the shield.

In one embodiment of the present invention, a plurality of the gas inlet channels extend diagonally downward in a direction towards the inner chamber.

In one embodiment of the present invention, the gas supply part further comprises a static-pressure chamber, and each gas inlet channel has an inlet and an outlet. The static-pressure chamber extends around the periphery of the shield and covers the inlets of a plurality of gas inlet channels. When the inert gas is injected into the static-pressure chamber, the inert gas enters the inner chamber through the inlets and the outlets of the gas inlet channels in turn.

In one embodiment of the present invention, the diameter of the part of the gas inlet channels close to the inlets gradually increases in a direction towards the static-pressure chamber.

In one embodiment of the present invention, the gas supply part further comprises a control element connected to the static-pressure chamber to control the flow rate and/or the pressure of an inert gas flowing into the static-pressure chamber.

As above, the electroplating device of the present invention has following advantages:

By arranging the first cover body and the second cover body, the first cover body is used to close the opening of the process chamber after the substrate holding device and the substrate are moved into the process chamber at the same time; the second cover body is used to close the opening of the process chamber after the substrate holding device and the substrate are moved out of the process chamber at the same time, so as to limit the inert gas in the closed space, and reliably prevent the external air from invading the inner chamber, so that the electroplating solution in the inner chamber can be effectively prevented from being oxidized without electroplating or electroplating. Therefore, the electroplating device provided by the present invention can maintain the stability of the electroplating solution, prolong the service life of the electroplating solution, save the cost of the electroplating solution, and facilitate production and management.

Other features and corresponding beneficial effects of the present invention are described later in the specification, and it should be understood that at least some of the beneficial effects become apparent from what is described in the specification of the present invention.

### BRIEF DESCRIPTION OF THE DRAWINGS

FIG. 1 shows a three-dimensional schematic diagram of an electroplating device according to the present invention;

FIG. 2 shows a schematic cross-sectional view showing an electroplating device provided by the present invention when the opening of the second cover body is closed;

FIG. 3 shows a schematic cross-sectional view of an electroplating device provided by the present invention when the opening of the first cover body is closed.

FIG. 4 shows a partial sectional view showing an electroplating device provided by the present invention when the opening of the first cover body is closed.

FIG. 5 shows a schematic view of a top-view structure after the opening of the process chamber of the electroplating device provided by the present invention is closed by a second cover body.

FIG. 6 shows a schematic diagram of a top view structure when the opening of the process chamber of the electroplating device provided by the present invention is open, and a schematic diagram of a top-view structure of the gas inlet channels is shown.

FIG. 7 shows a partial sectional view showing an electroplating device provided by the present invention.

### DETAILED DESCRIPTION OF EMBODIMENTS

The following describes the embodiments of the present invention through specific examples, those skilled in the art can easily understand other advantages and effects of the present invention from the content disclosed in this specification. Although the description of the present invention has been introduced together with the above preferred embodiments, it should be recognized that the features of the present invention should not be considered as limiting the present invention. On the contrary, the purpose of the presentation of the invention combining with embodiments is to cover other options or modifications that may be extended based on the claims of the present invention. In order to provide an in-depth understanding of the present invention, a number of specific details will be included in the following description. The present invention may also be implemented without these details. Further, in order to avoid confusing or obscuring the focus of the present invention, some specific details will be omitted from the description. It should be noted that embodiments of the present invention and features of embodiments may be combined with each other without conflict. It should be noted that in the specification, similar designations and letters denote similar terms in the following drawings, so that once an item is defined in one drawing, it is not necessary to further define and explain it in subsequent drawings.

The technical proposal of the present invention will be clearly and completely described combining with the accompanying drawings. It is obvious that the described embodiments are some embodiments of the present invention, not all of them. Based on the embodiments of the present invention, all other embodiments obtained without creative effort by those skilled in the art fall within the protection scope of the present invention.

In the description of the present invention, it should be noted that the terms “center”, “up”, “down”, “left”, “right”, “vertical”, “horizontal”, “inside”, “outside” and the like indicate the orientation or position relationship based on the orientation or position relationship shown in the accompanying drawings, only for the purpose of facilitating the description of the present invention and simplifying the description, and do not indicate or imply that the indicated device or element must have a specific orientation, be constructed and operated in a specific orientation, and therefore cannot be understood as a limitation of the present invention. In addition, the terms “first”, “second”, “third” are used for descriptive purposes only and cannot be understood as indicating or implying relative importance.

In the description of the present invention, it is to be noted that unless otherwise expressly specified and defined, the terms “install”, “link”, “connect” are to be understood in a broad sense, for example, may be fixed connection, may be detachable connection, or integrally connected; It can be a mechanical connection or an electrical connection; It can be directly linked, or indirectly linked through an intermediate medium, or it can be linked inside two components. For those skilled in the art, the specific meanings of the above-mentioned terms in the present invention can be understood in particular.

Embodiments of the present invention will be further described in detail below in conjunction with the accompanying drawings in order to make clearer the object, technical scheme and advantages of the present invention.

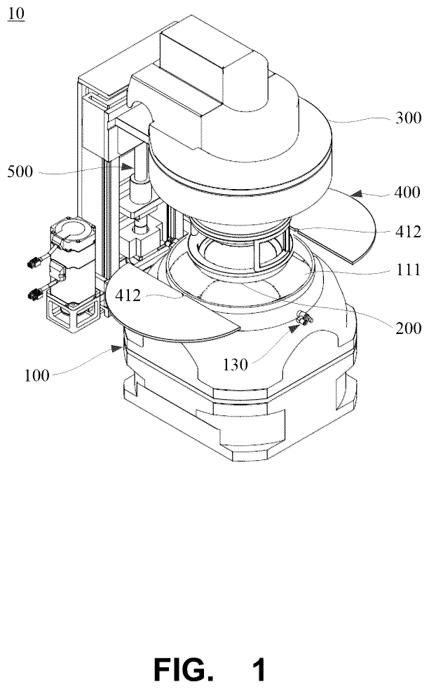

Please refer to FIG. 1 to FIG. 3, the electroplating device 10 provided by the present invention includes a process chamber 100, a substrate holding device 200, a first cover body 300, a second cover body 400, a gas supply part 130, and an exhaust part.

The inner chamber 110 of the process chamber 100 is used to hold the plating solution and has an opening 111. The inert gas is injected into the inner chamber 110 by the gas supply part 130, and the air is discharged from the inner chamber 110 by the exhaust part, so that a uniform positive pressure is formed in the inner chamber 110 by using the inert gas, and moisture and oxygen in the air are prevented from contacting the electroplating solution. In this embodiment, the exhaust part includes a first exhaust part 311 and a second exhaust part 411. The first exhaust part 311 is disposed on the first cover body 300, and the second exhaust part 411 is disposed on the second cover body 400. The inert gas used in this embodiment is nitrogen, and other inert gas such as argon, helium, and neon may also be used if necessary.

The substrate holding device 200 is used to hold the substrate, and the substrate holding device 200 is moved into or out of the inner chamber 110 through the opening 111. When electroplating is required, the substrate holding device 200 carries the substrate into the inner chamber 110 through the opening 111, so that the substrate is submerged in the electroplating solution. After the electroplating, the substrate holding device 200 carries the substrate out of the inner chamber 110 through the opening 111, and the substrate moves onto the next process.

The first cover body 300 is connected to the substrate holding device 200 and moves synchronously with the substrate to close the opening 111 after the substrate holding device 200 is moved into the inner chamber 110, so that the inner chamber 110 is in a closed state. In this embodiment, the process of the substrate holding device 200 moving into the inner chamber 110 is: the substrate holding device 200 carries the substrate down vertically until it moves into the inner chamber 110.

The process of the substrate holding device 200 moving out of the inner chamber 110 is as follows: after the electroplating is completed, the substrate holding device 200 carries the substrate up vertically until the inner chamber 110 is moved out. At the same time, the first cover body 300 is also far away from the opening 111. At this time, the second cover body 400 is used to close the opening 111, so that the inner chamber 110 is also in a closed state when the electroplating is not carried out. The inert gas is confined in the closed space, and the oxidation of the electroplating solution is effectively prevented.

Consequently, when the substrate holding device 200 is moved into the inner chamber 110 and when the substrate holding device 200 is moved out of the inner chamber 110, the inner chamber 110 is in a closed state. The air in the inner chamber 110 is extruded by the inert gas, so that a uniform positive pressure is formed in the inner chamber 110. It prevents moisture and oxygen in the air from contacting the electroplating solution, prevents the electroplating solution from oxidizing, maintains the stability of the electroplating solution, prolongs the service life of the electroplating solution, and saves the cost of the electroplating solution.

The first cover body 300 is a rotary driving device, and the rotary driving device drives the substrate holding device 200 to rotate in the inner chamber 110 about the axis O of the rotary driving device. By using the electroplating device 10 itself (namely the rotary driving device) to achieve the function of the first cover body 300, the movable parts are omitted and the cost is reduced.

In other alternative embodiments, the first cover body 300 may also be an alternative member capable of closing the opening 111 after the substrate holding device 200 is moved into the inner chamber 110 so that the inner chamber 110 is in a closed state.

The electroplating device 10 further comprises a lifting driving device 500 connected to the substrate holding device 200 by a rotary driving device to drive the substrate holding device 200 into or out of the inner chamber 110.

After the lifting driving device 500 drives the substrate holding device 200 into the inner chamber 110, the rotary driving device covers the opening 111 to close it.

Furthermore, when the first cover body 300 is a rotary driving device, an enclosure 310 is provided along the circumferential direction of the lower surface of the rotary driving device facing the opening 111. When the rotary driving device covers the opening 111, the enclosure 310 is in contact with the edge of the opening 111.

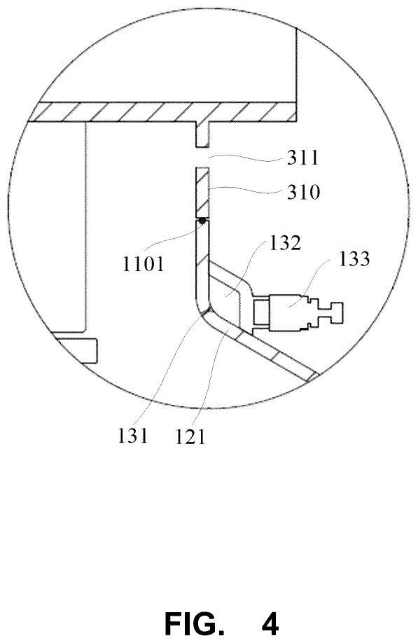

Please refer to FIG. 4, a sealing ring 1101 is provided between the enclosure 310 and the edge of the opening 111 of the process chamber 100 to prevent air from entering the inner chamber 110.

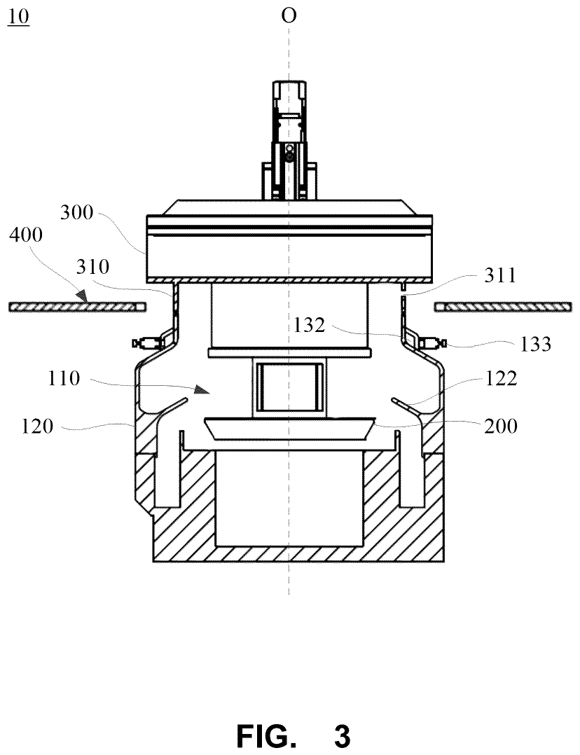

Please refer to FIG. 3 and FIG. 4, the diameter of the enclosure 310 is the same as the diameter of the opening 111. When the rotary driving device covers the opening 111, the sealing ring 1101 is provided at the bottom of the enclosure 310 or at the top of the edge of the opening 111.

It will be appreciated by those skilled in the art that in alternative other embodiments, the diameter of the enclosure 310 may also be greater than the diameter of the opening 111 or smaller than the diameter of the opening 111.

If the diameter of the enclosure 310 is greater than the diameter of the opening 111, the sealing ring 1101 is provided on the inner wall of the enclosure 310 or on the outer wall of the edge of the opening 111. If the diameter of the enclosure 310 is smaller than the diameter of the opening 111, the sealing ring 1101 is provided on the outer wall of the enclosure 310 or on the inner wall of the edge of the opening 111. As long as the sealing ring 1101 is provided between the enclosure 310 and the edge of the opening 111 and it is possible to prevent air from entering the inner chamber 110, so that the inert gas is in a relatively sealed space. The present invention does not limit the magnitude relationship between the diameter of the enclosure 310 and the diameter of the opening 111.

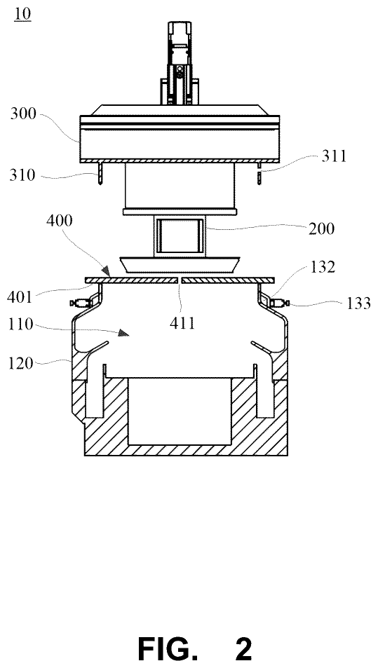

As shown in FIG. 2, when the lifting driving device 500 drives the substrate holding device 200 out of the inner chamber 110, the rotary driving device also moves away from the opening 111. At this time, the opening 111 is closed by the second cover body 400, so that the inner chamber 110 is closed again.

The second cover body 400 includes two cooperating cover plates, the two cover plates are on the same plane, and the two cover plates are moved opposite or backward in the radial direction of the opening 111, so that the opening 111 is closed or opened.

When the substrate holding device 200 is moved out of the inner chamber 110, the two cover plates are moved towards the center of the opening 111 to close the opening 111. When the substrate holding device 200 is required to move into the inner chamber 110, the two cover plates move backwards away from the center of the opening 111, opening the opening 111.

Also, sealing ring (not shown in the figure) is selectively provided or not provided between the two cover plates and the edges of the opening 111.

When the sealing ring is not provided between the second cover body 400 (namely the two cover plates) and the edge of the opening 111, the process of the second cover body 400 closing the opening 111 is that the two cover plates respectively located on both sides of the opening 111 move opposite each other along the radial direction of the opening 111 until they are in close contact with each other, so as to achieve the effect of closing the opening 111.

When a sealing ring is provided between the second cover body 400 and the edge of the opening 111, the sealing ring is provided at the bottom 401 of the second cover body 400 or at the top of the edge of the opening 111. In this case, the sealing ring needs to be considered in the process when the second cover body 400 closes the opening 111. Specifically, when the sealing ring is provided at the bottom 401 of the second cover body 400, the process of the second cover body 400 (namely the two cover plates) closing the opening 111 may be as follows: move the two cover plates on each side of the opening 111 in radial direction along the opening 111. When the sealing ring on the two cover plates is close to the edge position of the opening 111, raise the two cover plates, then continue to move them in the opposite direction until they merge with each other, and finally lower the two cover plates to cover the opening 111, thereby achieving the purpose of the second cover body 400 to close the opening 111.

The above process can also be: before the two cover plates begin to merge, position the two cover plates above the opening 111, then move the two cover plates opposite each other from the two sides of the opening 111 until merged, and finally lower the two cover plates and cover the opening 111. Therefore, this prevents the sealing ring on the cover plates from affecting the smooth merging of the two cover plates.

Similarly, when the sealing ring is provided at the top of the edge of the opening 111, the process of the second cover body 400 (namely the two cover plates) closing the opening 111 can be: moving the two cover plates from both sides of the opening 111 towards each other, moving up the two cover plates when they are close to the sealing ring position on the opening 111, then continuing to move towards each other until they merge with each other, and finally lowering the two cover plates to cover the opening 111, thereby achieving the purpose of closing the opening 111. The process may also involve: placing the two cover plates above the sealing ring at the top of the opening 111 before the two cover plates begin to merge, then moving towards each other until merged, and finally descending to cover the opening 111. This prevents the sealing ring at the top of the edge of the opening 111 from affecting the smooth merging of the two cover plates.

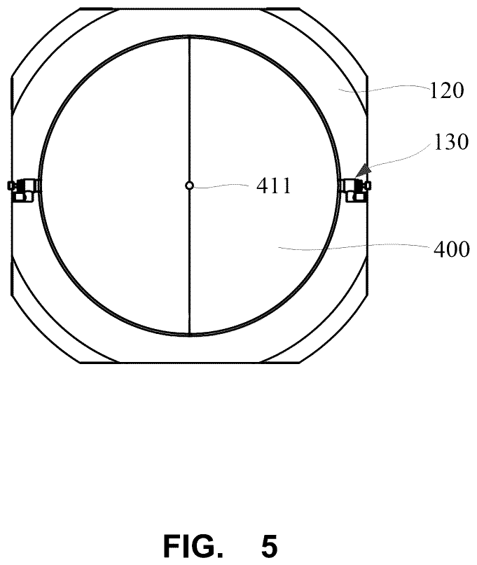

Please refer to FIG. 1, FIG. 4, and FIG. 5, the first exhaust part 311 is a first exhaust hole provided in the enclosure 310, and the second exhaust part 411 is a second exhaust hole provided in the second cover body 400. A notch 412 is provided on each side where the two cover plates of the second cover body 400 are in contact with each other to form a second exhaust hole.

After the inert gas passes through the gas supply part 130 into the inner chamber 110, the inert gas discharges air from the first exhaust hole or the second exhaust hole outside the process chamber 100.

It is understood by those skilled in the art that in alternative other embodiments, the second cover body 400 may also be a whole, and the position of the second exhaust hole may be provided in the middle or near the edge of the second cover body 400 according to practical needs.

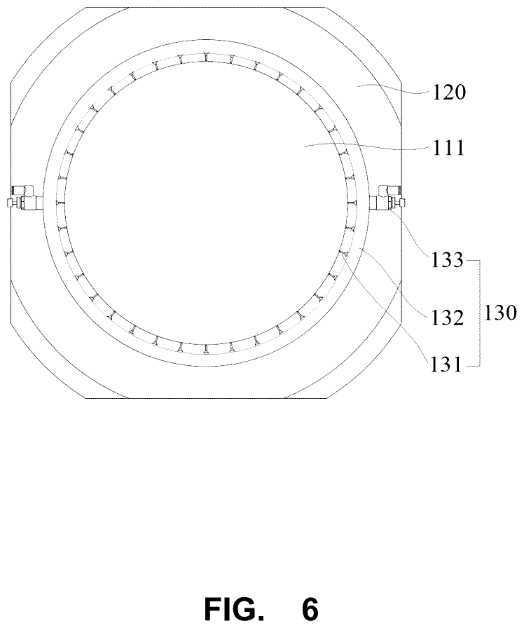

Please refer to FIG. 3, FIG. 4 and FIG. 6, the process chamber 100 includes a shield 120 in which a gas supply part 130 is provided, and the gas supply part 130 includes a plurality of gas inlet channels 131 which are evenly spaced along the circumference of the shield 120 and pass through the sidewall 121 of the shield 120. The inert gas is passed into the inner chamber 110 of the process chamber 100 from a plurality of gas inlet channels 131, so that the inert gas in the inner chamber 110 is uniformly distributed to achieve the effect of sufficiently preventing oxygen from contacting the electroplating solution.

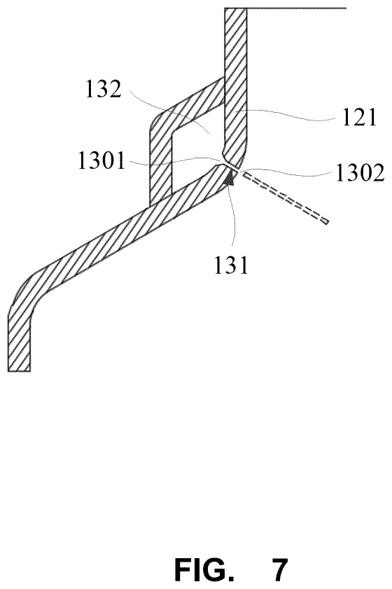

Please refer to FIG. 3 and FIG. 7, the electroplating solution is generally located below the water retaining ring 122 of the shield 120, and the water retaining ring 122 is capable of preventing the electroplating solution from splashing below. The position of the plurality of gas inlet channels 131 is higher than the position of the electroplating solution, and the plurality of gas inlet channels 131 extend obliquely downwards in the direction towards the inner chamber 110, so that inert gas passes through the plurality of gas inlet channels 131 towards the inner chamber 110 in the direction of the electroplating solution, and extrudes the air out of the process chamber 100. The dotted line in FIG. 7 indicates the direction of the inlet path of the inert gas.

Please refer to FIG. 4, FIG. 6, and FIG. 7, the gas supply part 130 further includes a static-pressure chamber 132 which extends around the outer periphery of the shield 120 in an annular shape. Each gas inlet channel 131 has an inlet 1301 and an outlet 1302, and the static-pressure chamber 132 wraps around a plurality of inlets 1301.

When inert gas is injected into the static-pressure chamber 132, the inert gas enters the inner chamber 110 through the inlets 1301 and the outlets 1302 of the gas inlet channels 131 in turn. The static-pressure chamber 132 is provided so that the inert gas pressure uniformly passes through the plurality of gas inlet channels 131 into the inner chamber 110.

The gas inlet channel 131 may be of a hole type, a nozzle type, a gas knife type, or the like. In this embodiment, the gas inlet channel 131 adopts a hole structure, and the diameter at the position of the inlet 1301 of the gas inlet channel 131 is gradually increased in the direction towards the static-pressure chamber 132 to play a cushioning role.

The gas supply part 130 further comprises a control element 133 connected to the static-pressure chamber 132 to control the flow rate and/or pressure of the inert gas flowing into the static-pressure chamber 132. The control element 133 includes at least one of a manual valve, an electric valve, a solenoid valve, a valve with flow control, or a valve with pressure control.

Finally, it should be recognized that: the above embodiments are only used to illustrate the technical scheme of the present invention, but not to be considered as limiting the present invention; Although the content of the present invention has been described in detail through the above preferred embodiments, it should be understood by those skilled in the art that the technical scheme described in the aforementioned embodiments can still be modified, or some or all of the technical features thereof can be equivalent replaced; These modifications or substitutions do not make the essence of the corresponding technical scheme deviate from the scope of the present invention.

1. An electroplating device, comprising:
a process chamber, having an inner chamber for holding the electroplating solution, the inner chamber having an opening;
a substrate holding device, holding a substrate and moving into or out of the inner chamber through the opening;
a first cover body, connected to the substrate holding device to close the opening after the substrate holding device is moved into the inner chamber so that the inner chamber is in a closed state;
a second cover body, closing the opening after the substrate holding device is moved out of the inner chamber so that the inner chamber is in a closed state;
a gas supply part, introducing an inert gas into the inner chamber; and
an exhaust part, discharging air from the inner chamber.

2. The electroplating device according to claim 1, wherein the first cover body is a rotary driving device, and the rotary driving device drives the substrate holding device to rotate in the inner chamber around the axis of the rotary driving device;
when the substrate holding device is moved into the inner chamber, the rotary driving device covers the opening so as to close the opening.

3. The electroplating device according to claim 1, wherein an enclosure is provided along the circumferential direction of the lower surface of the first cover body towards the opening;
when the first cover body covers the opening, the enclosure is in contact with an edge of the opening.

4. The electroplating device according to claim 1, wherein a sealing ring is provided at a position where the opening is combined with the first cover body or the second cover body.

5. The electroplating device according to claim 1, wherein the second cover body comprises two cover bodies that cooperate with each other, and both cover bodies are at the same plane;
after the substrate holding device is moved out of the inner chamber, the two cover bodies are moved towards the center of the opening to close the opening.

6. The electroplating device according to claim 1, wherein the exhaust part comprises a first exhaust part and a second exhaust part, the first exhaust part is provided in the first cover body and the second exhaust part is provided in the second cover body.

7. The electroplating device according to claim 1, wherein the process chamber comprises a shield, the gas supply part is arranged on the shield, and the gas supply part comprises a plurality of gas inlet channels, which are arranged at intervals along the circumferential direction of the shield and pass through the side wall of the shield.

8. The electroplating device according to claim 7, wherein a plurality of the gas inlet channels extend diagonally downward in a direction towards the inner chamber.

9. The electroplating device according to claim 7, wherein the gas supply part further comprises a static-pressure chamber, and each gas inlet channel has an inlet and an outlet;
the static-pressure chamber extends around the periphery of the shield and covers the inlets of a plurality of gas inlet channels;
when the inert gas is injected into the static-pressure chamber, the inert gas enters the inner chamber through the inlets and the outlets of the gas inlet channels in turn.

10. The electroplating device according to claim 9, wherein the diameter of the part of the gas inlet channels close to the inlets gradually increases in a direction towards the static-pressure chamber.

11. The electroplating device according to claim 9, wherein the gas supply part further comprises a control element connected to the static-pressure chamber to control the flow rate and/or the pressure of the inert gas flowing into the static-pressure chamber.
